(19) United States
(12) Patent Application Publication
(10) Pub. No.: US 2007/0182025 A1
(43) Pub. Date: Aug. 9, 2007

(54) Laminate structure and method of producing the same

(75) Inventor: Lars Sandberg, Hammaro (SE)

Correspondence Address: GREER, BURNS & CRAIN, 300 S WACKER DR, 25TH FLOOR, CHICAGO, IL, 60606, US

(73) Assignee: Stora Enso AB

(21) Appl. No.: 11/488,360

(22) Filed: Jul. 18, 2006

Related U.S. Application Data
(60) Provisional application No. 60/765,854, filed on Feb. 7, 2006.

(51) Int. Cl. H01L 23/48

(52) U.S. Cl. 257/783

(57) ABSTRACT

The invention relates to a laminate structure comprising a first carrier layer with a surface, a first active surface being electrically conducting and being supported by the first carrier layer, a second active surface being electrically conducting and being supported by the first carrier layer, wherein the first active surface is separated from the second active surface a first distance along the surface of the first carrier layer, wherein the laminate structure is adapted to receive an electrically weakable adhesive bridging said distance between the active surfaces. The invention further relates to a method of producing such a laminate structure.

### FIELD OF INVENTION

The invention relates to a laminate structure comprising a first carrier layer with a surface, a first active surface being electrically conducting and being supported by the first carrier layer, a second active surface being electrically conducting and being supported by the first carrier layer.

The invention further relates to a method of producing such a laminate structure.

### TECHNICAL BACKGROUND

The old way of distributing products in large distribution packages, followed by repacking of the products behind the store counter in paper bags, or the like, in the amount as bought by the consumer, has almost completely disappeared. Decades ago the wide spread of the large self service stores, with pre-packed products stored on shelves, from which the consumers themselves pick the products, lead to great developments in the packaging industry.

Today almost all consumer products are packed at the manufacturing or processing site, distributed, sold, and often also stored in the consumers home, in one and the same package. One popular kind of package used for almost all kind of products is a box made of paperboard. Paperboard boxes are, e.g., widely used for dry food products and for small commodity items such as screws and nails. By providing an inner bag the paperboard box may also be used for liquids or for powder products, such as cocoa or dry milk. This kind of package is also widely used for cereals and similar products.

This kind of package is often adapted to be opened by first tearing off a tearing band or strip from the paperboard box and then cutting (with a pair of scissors) the inner bag open. The tearing band often extends across the complete top surface, from side edge to side edge, and separates a front flap connected with the front side of the container from a rear flap connected to the back side of the package. The front and rear flaps are often spot glued to side flaps folded from the sides of the package underneath the front and rear flaps. When the consumer opens such a package the tear band often breaks and the tearing action need to be restarted again. Moreover, the tear band often does not separate from the flaps as intended, which makes it more difficult to open the package and which often results in that any reclosing means, such as flaps and slits, are damaged.

Another kind of package often used as a consumer package is a bottle or jar formed of plastic or glass provided with a screw cap or snap lid formed of plastic or metal. This kind of package has an intrinsic problem relating to the compromise of providing a sufficiently low initial opening force and a sufficiently good sealing. Most caps or lids on this kind of package are fastened by threads or bayonet mount. In order to provide the necessary sealing pressure, the caps or lids must be fastened with a significant torque. Within the packaging industry there exist numerous variants concerning how to avoid the need for application of a high torque for closing the package. However, as will be discussed below, these variants introduce different drawbacks for the consumers when opening the packages, and especially at initial opening of the packages.

One kind of package often used for jam, pickled gherkin, and the like is a glass jar with a metal lid. Such a package is often filled by hot-filling or the like in order to create a negative pressure inside the jar. This negative pressure will force the lid against the mouth of the jar and will thereby improve the quality of the sealing between the lid and jar. However, this way of creating a good seal has the drawback that it is very hard to open such a jar; when trying to rotate the lid, the negative pressure will give rise to a high friction force counteracting the intended opening action. This kind of package also requires that the jar and lid are formed of relatively rigid components in order to be able to withstand the forces involved.

One kind of package often used for dry products, such as instant coffee, is a glass jar with a simple plastic lid. In order to provide sufficient sealing, the jar is, underneath the lid, provided with a sealing film or membrane. Such a sealing membrane is often also provided on plastic bottles for ketchup, mustard or the like, and boxes for table margarine or the like, where the lid has a snap functionality or some other functionality which is difficult to use to provide a sealing action. The film or membrane is often glued or fused to the mouth of the package. However, this kind of package suffers from the drawback that the necessary tearing off force must be sufficiently low for the user to be able to tear off the membrane and preferably in one piece, but the membrane should also be securely sealed to the mouth and it should from cost and environment aspects be as thin as possible. The result is often that the consumer has difficulties in tearing off the membrane at all or in tearing off the membrane in one piece. The membrane is only partially torn off, it is often difficult to get rid of the remainders since any grip tab or the like has already been torn off.

Thus, the known packages all suffer from different drawbacks when it comes to opening of the packages.

Common for all kinds of consumer packages is that they contain consumer adapted volumes or amounts of the product in question. This gives that the consumer packages each have a relatively small volume compared to the total volume sold by each store and even smaller compared to the total volume distributed to a number of stores in the same distribution area. It is not practical for the store or distribution personnel to handle every single consumer package one by one. This is one major reason for the wide spread use of distribution packages housing several consumer packages.

One commonly-used distribution package is a corrugated cardboard box enclosing the consumer packages. The corrugated cardboard is usually folded to form an open ended box, filled with the consumer packages and closed by gluing together two or more flaps. In automatic processes it is also common to gather several consumer packages side by side and then the corrugated cardboard box is formed by basically wrapping the cardboard about the consumer packages and finally close it by gluing together one or more flaps. Cardboard boxes are usually opened by either cutting the cardboard using a knife, tearing the glued flaps open by hand, or tearing the cardboard along perforations by hand. Using a knife introduces the risk of personnel injuries or damages to the consumer packages. In order to avoid handling the consumer packages one by one, it is often also desirable to be able to keep a part of the distribution package as a bottom tray or the like, making it possible to put several consumer packages onto the shelf in one heave. Such a package is usually designed to be opened by a tearing action. However, the cardboard box is often torn apart instead of simply torn open, when the store personnel tears the glued flap open or tears the cardboard along any perforation. This is not satisfactory since it will give an impression of low quality reflecting negatively on the product and the store. Since the tray usually need to be provided with a rim, i.e. a lower portion of the side walls need to be left, in order to provide the necessary stability, it is difficult to open such a distribution package using a knife without damaging the consumer packages. The cardboard box may alternatively be closed using interlocking flaps. However, it is often hard to accomplish an automatic closing of such a box. Moreover, the flaps often need to be removed by a tearing or cutting action when the box is to be put on the store shelf. Thus this kind of box is also associated with the problems relating to tearing or cutting of the cardboard as discussed-above.

A simple and cheap way of providing a distribution package is to plastic film wrapping several consumer packages. This requires however often that the consumer packages as such are relatively form stable. When the consumer packages are to be put on the store shelves, the store personnel cuts the film wrapping open, using a knife, and put the consumer packages one by one on the shelf. The use of a knife introduces the risk of personnel injuries or damages to the consumer packages. Moreover, the store personnel still has to handle the consumer packages one by one. By putting the consumer packages on a tray and then film wrap the tray together with the consumer packages, this one by one handling may be avoid. This kind of distribution package is often used for metal cans, plastic bottles and plastic tubes distributed standing up on the tray. However, the film wrapping still has to be cut open.

Consumer packages and distribution packages have been used wide spread for several decades within almost every line of business but as has been discussed above the different kind of distribution packages are all associated with different problems.

### SUMMARY OF INVENTION

It is an object of the invention to provide a laminate structure which may be used to eliminate or at least to reduce the above mentioned problems. The inventive laminate structure may be used in other applications than the ones discussed above and in the detailed description.

The above objective has been achieved with a laminate structure comprising a first carrier layer with a surface, a first active surface being electrically conducting and being supported by the first carrier layer, a second active surface being electrically conducting and being supported by the first carrier layer, wherein the first active surface is separated from the second active surface a first distance along the surface of the first carrier layer, wherein the laminate structure is adapted to receive an electrically weakable adhesive bridging said distance between the active surfaces.

In this way, it is possible to pre-manufacture parts of the structure with the active surfaces on a carrier layer. When applying the laminate structure to a package or to a connecting element a number of advantages are achieved.

It may be noted that supported does not necessarily mean that the active surfaces need to be in direct contact with the first carrier layer. In one embodiment the first active surface is laminated directly onto the first carrier layer, whereas significant portions of the second active surface is laminated onto an insulating layer laminated onto the first active surface. The laminate structure is still supported by the first carrier layer.

As mentioned above, glued cardboard packages are today often provided with a tear strip. By using the inventive laminate structure it is possible to introduce a new design of the package, whereby there is no longer any need for such a tear strip. The package is glued together at filling of the package using an electrically weakable adhesive. When the consumer would like to open the package, a voltage is applied to the electrically weakable adhesive and the adhesive looses its adhesive force. The package is thereafter easily opened without any risk of being incorrectly torn open and without any risk of damaging any reclosure tabs/slots or the like. The package with inventive laminate structure and the electrically weakable adhesive may also be designed or configured in a manner not possible today. When designing a conventional package, the designer must balance design requirements relating to erecting and closing of the container with design requirements relating to opening of the container. This often results in that the closing of the container is unnecessary complicated and still it is hard to open the container as intended. This problem is eliminated or at least greatly reduced with a package using the inventive laminate structure. It is e.g. possible to design the container in a way that gives a simple erecting and closing of the container by simply using adhesive connections where connection is desired. When the user wants to open the package a voltage is applied to the electrically weakable adhesive, and the desired connections are easily released. In this way it is further possible to design the package to be as strong as possible without the need for any far-reaching compromises concerning how to still make opening of the package easy. The package is in any case simply opened by the application of a voltage to the electrically weakable adhesive.

Similarly, for a package with a body and a cap the introduction of the inventive laminate structure makes it possible to provide a package which is tightly closed in distribution and which still is easily opened. The laminate structure with the electrically weakable adhesive may, e.g., be used to secure a screw cap from unintentionally being screwed of the bottle and, after being subjected to a voltage, still easily release the cap from the bottle when the package is to be opened. This may also be used for a foil covered opening. The foil is securely fastened to the mouth of the bottle or jar by forming part of the inventive laminate structure with the electrically weakable adhesive. When the package is to be opened, a voltage is applied and the foil is easily removed. Thereby it is possible to even fasten the foil so securely that it is impossible to tear it off without applying a voltage. In any case it is possible to secure the foil to a greater extent than today and still make it possible to release it much easier than today. With this difference in securing power it is possible to design very thin foils, since they after application of a voltage only have to withstand any remaining tear-off resistance instead of as today where they during tear-off have to withstand the original tear-off resistance being designed to be high enough to keep the foil secured to the package during distribution.

The use of the inventive laminate structure with a electrically weakable adhesives also allows for the application of a tamper-proof feature integrally formed with the initial closure of the package. When the electrically weakable adhesive has reacted, it will no longer return to the same strong adhesive strength and it will thereby provide a tamper-proof feature.

The voltage applied may be either alternating or direct depending upon the desired manner of weakening of the electrically weakable adhesive. The voltage may e.g. be applied by an external source, such as a battery, by electromagnetic waves, or by designing the package with active surfaces of different materials with different electrode potentials, thereby forming an internal battery.

The inventive laminate structure may also be used in a connecting element provided with adhesion areas comprising an electrically weakable adhesive. With this connecting element it is possible to provide new kinds of distribution solutions. The connecting element may be used to hold together packages or other kinds of products and articles.

It may e.g. be formed as board shaped members arranged beneath or on top of a pallet of packages. By holding the packages to the connecting element, the set of packages and connecting element will form a distribution unit with improved handleability. When the shop assistant has placed the distribution unit in place on the display shelf, the packages are easily released by application of voltage to the electrically weakable adhesive. Since there is no need for any tearing or cutting of any distribution package, there is no need for any additional space between the products or packages and the surrounding display shelves. In accordance with one embodiment the shop assistant simply slides a set of eight packages from the pile of product on the pallet lifter to the display shelf, the packages being held together by an underlay and a top board. Thereafter the assistant activates the internal battery applying a voltage to the adhesion areas with the electrically weakable adhesive and thereby releasing the top board from the packages. The assistant withdraws the top board from the display shelf and finalises the loading of the shelf with activation of the internal battery of the underlay, thereby releasing the packages also from the underlay. When the consumer picks the packages from the shelf they are easily picked from the shelf and underlay since they are already released from the underlay. It is also contemplated that in some cases the packages are released from the connecting element used during distribution and then put one by one on the display shelf.

The inventive laminate structure may also be used in a package comprising a first adhesion area by which adhesion area said package is adapted to be temporarily connected to one or more other packages, wherein the adhesion area comprises an electrically weakable adhesive. A set of packages are held together during distribution by one or more packages provided with the electrically weakable adhesive. Numerous variations concerning when to release the packages are contemplated. The shop assistant lifts the set of packages to the display shelf and then releases them to leave them arranged together but released from each other. In this way it will be possible to make use of the distribution solution for the shop assistant whereas the consumer does not notice any difference compared to the solution of today. It is also contemplated to release them and then putting them one by one on the shelf. This is suitable if the packages are to heavy or bulky to handle in sets of packages. It is also contemplated that the packages are released from the neighboring packages by the consumer when lifting them from the shelf. This gives information to the consumer that this package has not been released before. This is e.g. useful for cooled or frozen products; if you have to release it you know that no other consumer has walked around in the store with the product in the shopping cart and then changed his or her mind and put it back in the freezer. It is also contemplated that the packages are bundled together and sold together and only separated when the consumer puts the products in the cabinets at home or even when he or she is about to open the package. This may e.g. be used for selling a primary product, and one or more associated products, such as pasta and pasta sauce, as a bundled package.

The inventive laminate structure may also be used in an article forming a handling element comprising a first adhesion area, adapted to temporarily holding at least one secondary article to said handling element, and an engagement area by which the handling element and the secondary article connected thereto are adapted to be handled, wherein the adhesion area comprises an electrically weakable adhesive. Such a design is e.g. useful for handling and displaying consumer articles on a rack. It may e.g. be used to display pencils or similar products that today are put behind a plastic cover on a paper board. The electrically weakable adhesive may be used to connect the article directly to the paper board.

It may be noted that most of the advantages has been discussed in respect of the complete product comprising the first and the second carrier layer and the electrically weakable adhesive. As mentioned initially one advantage of the inventive laminate structure is that it is possible to pre-manufacture the laminate structure in different steps and at different locations. The carrier layer may, e.g., be manufactured at a first location and then afterwards be provided with the active surfaces. The active surfaces may be provided using a printing technique where conductive ink is applied to the carrier layer. The active surfaces may also be formed of conductive foils laminated as foils or as molten materials to the carrier layer. Such a laminate structure may then be stored or distributed as a unit. It may also form part of a package or some other final product. The electrically weakable adhesive may then as a separate step be provided to the laminate structure when the intended products or portions of a product is to be connected to each other. Other variants of this possibility to pre-manufacture the laminate structure in different levels from the carrier layer to the complete laminate structure will follow from the description of preferred embodiments.

Preferred embodiments of the invention appear from the dependent claims.

The first carrier layer may be formed of a non-conductive material. In this way the conductors may simply be provided as printed or laminated conductors on the non-conductive material. There will be no immediate need for more complicated laminate structures with insulating layers, etc.

The first carrier layer may be formed of paper board. This material is preferred since it is easy to provide a connecting element or package in paper board. It is also normally non-conducting making it easy to provide it with an electrical circuitry using e.g. a printing or laminating technique.

The laminate structure may comprise an internal source of electrical power adapted to be activated or connected to the active surfaces to in a closed electrical circuit apply a voltage to the electrically weakable adhesive. In this way the package or connecting element may be released anywhere and by anyone. This is especially useful for solutions where the packages are released by the consumer when he or she picks them from the shelf and for solutions where bundled packages are to be released after being purchased.

The first active surface may be of a first material with a first electrode potential, and the second active surface may be of a second material with a second electrode potential, and wherein the first electrode potential differs from the second electrode potential. In this way, the active surfaces as such will act as an internal electrical source and will when connected to each other via a electrical circuitry outside the electrically weakable adhesive form a closed electrical circuit applying a potential difference across the electrically weakable adhesive.

The laminate structure may further comprise at least one printed and/or laminated battery. This is an expedient way of providing an internal source of electrical power.

The at least one printed and/or laminated battery may be printed on a first carrier layer. This is an expedient way of providing a battery forming an internal source of electrical power. As indicated below the first carrier layer may also be used to carry on or more active surfaces. Thereby it is easy to provide a connection between the battery and the one or more active surfaces on the first carrier layer.

A portion of at least one of said active surfaces may be exposed and adapted to be covered by said adhesive. In this way the electrically weakable adhesive will in itself provide the conductive bridge to this active surface.

At least a portion of the first active surface and at least a portion of the second active surface may be exposed and adapted to be covered by said adhesive. In this way the electrically weakable adhesive will in itself provide the conductive bridge to both active surfaces.

The active surfaces may be shaped such that a projection of the first active surface on the surface of the first carrier layer essentially surrounds a projection of the second active surface on the surface of the first carrier layer. In this way the area in which the electrically weakable adhesive will be broken or weakened will be relatively large compared to the size of the active surfaces. In this way the energy losses due to resistance in the active surfaces will be minimized. It will furthermore provide a rather concentrated weakening of the adhesive, which will facilitate the opening of the package.

A projection of the first active surface on the surface of the first carrier layer and a projection of the second active surface on the surface of the first carrier layer may at least partly overlap each other, wherein the laminate structure further comprises an insulating layer provided between the first and second active surfaces, at least at the overlap. By providing active surfaces with overlaps and insulating layers there between it is possible to optimise the shape of the electrically weakened area, without having to be limited by separation in the plane of the carrier layer.

The first active surface may be formed as a closed loop with its projection on the surface of the first carrier layer surrounding the projection of the second active surface on the surface of the first carrier layer, wherein the second active surface has a connecting portion extending out of the closed loop of the first active surface, and wherein the electrically insulating layer separates the connecting portion of the second active surface from the first active surface. In this way the electrical potential will be bridged by the electrically weakable adhesive to the first active surface all the way around the second active surface. This will give a relatively large weakened area compared to the size of the second active surface.

The laminate structure may further comprise an electrically weakable adhesive bridging said distance between the first and second active surfaces, and being adapted to be located between the active surfaces and a second carrier layer. It may e.g. be noted that the laminated structure may be sold to a producer of a complete product or package, the laminated structure being provided with active surfaces but without any electrically weakable adhesive thereon. The electrically weakable adhesive may then be applied when the package is to be closed or an article is to be connected to another using the laminated structure with the electrically weakable adhesive.

The laminate structure may further comprise a non electrically weakable adhesive arranged as a layer adapted to be located between the electrically weakable adhesive and a second carrier layer. In this way it is possible to pre-manufacture the structure with active surfaces and electrically weakable adhesive and then to apply a conventional adhesive on top of this when e.g. the package is closed for the first time. When the package is to be opened the electrically weakable adhesive is weakened and the conventional adhesive will be released together with the portion or package member not carrying the active surfaces. It is also contemplated to provide two layers of electrically weakable adhesive, one layer in the pre-manufacturing step and a second layer when e.g. the package is to be closed.

The laminate structure may further comprise a second carrier layer adhered to the first carrier layer and the active surfaces by said electrically weakable adhesive or said non electrically weakable adhesive.

The first carrier layer may form part of a first portion of a package and the second carrier layer may form part of a second portion of a package, wherein the first and second portions of the package is adapted to be connected to each other and thereby keep the package closed.

The first carrier layer may form part of a first package member and the second carrier layer may form part of a second package member, wherein the first and second package members are adapted to co-operate with each other and thereby form a closed package.

The electrically weakable adhesive may form a sealing layer. In this way it is possible to e.g. form a securely sealed package which still may be easily opened.

The laminate structure may also provide a connecting element wherein the first carrier layer forms part of the connecting element adapted to temporarily holding together a plurality of articles, the connecting element comprising a base member provided with a first adhesion area adapted to hold a first secondary article to said base member and a second adhesion area adapted to hold a second secondary article to said base member, wherein the adhesion areas comprise an inventive laminate structure. With this connecting element it is possible to provide new kinds of distribution solutions. The connecting element may be used to hold together packages or other kinds of products and articles. The advantages and different embodiments of such a connecting element has been discussed in more detail above with respect to different manners of making use of the inventive laminate structure.

The above disclosed laminated structure may also be used to provide an article forming a handling element comprising a first adhesion area, adapted to temporarily holding at least one secondary article to said handling element, and an engagement area by which the handling element and the secondary article connected thereto are adapted to be handled, wherein the adhesion area comprises an electrically weakable adhesive. Such a design is, e.g., useful for handling and displaying consumer articles on a rack. It may e.g. be used to display pencils or similar products that today are put behind a plastic cover on a paper board. The electrically weakable adhesive may be used to connect the article directly to the paper board.

The above objective has also been achieved by a method of producing a laminate structure, the method comprising providing a first carrier layer, providing a first active surface being electrically conducting and being supported by the first carrier layer, providing a second active surface being electrically conducting, supported by the first carrier layer and separated from the first active surface a first distance along the surface of the first carrier layer, and providing a layer of an electrically weakable adhesive at least partly bridging said distance between the first and second active surfaces.

It may be noted that most of the advantages has been discussed in respect of the complete product comprising the first and the second carrier layer and the electrically weakable adhesive. As mentioned initially one advantage of the inventive laminate structure is that it is possible to pre-manufacture the laminate structure in different steps and at different locations. This is disclosed by the inventive method.

The carrier layer may e.g. be manufactured at a first location and then afterwards be provided with the active surfaces. The active surfaces may be provided using a printing technique where conductive ink is applied to the carrier layer. The active surfaces may also be formed of conductive foils laminated as foils or as molten materials to the carrier layer. Such a laminate structure may then be stored or distributed as a unit. It may also form part of a package or some other final product. The electrically weakable adhesive may then as a separate step be provided to the laminate structure when the intended products or portions of a product is to be connected to each other. Other variants of this possibility to pre-manufacture the laminate structure in different levels from the carrier layer to the complete laminate structure will follow from the description of preferred embodiments.

Preferred embodiments of the invention follows from the dependent claims.

The method may further comprise providing an electrically weakable adhesive onto the laminate structure such that it bridges said distance between the active surfaces. As mentioned above the electrically weakable adhesive may then as a separate step be provided to the laminate structure when the intended-products or portions of a product is to be connected to each other.

The advantages of respective feature of the-dependent claims has been discussed in detail with respect to the corresponding features of the dependent claims relating to the laminate structure and will not be repeated with respect to the preferred embodiments of the method. Reference is made to the detailed discussion above.

A portion of at least one of said active surfaces may be exposed and wherein the adhesive is provided onto the laminate structure such that it covers said portion.

At least a portion of the first active surface and at least a portion of the second active surface may be exposed and wherein the adhesive may be provided onto the laminate structure such that it covers said portions.

The active surfaces may connectable to each other via an electrical circuit comprising a switch member by which the circuit may be closed or opened. This is a simple way of providing a way of in a controlled manner apply a voltage to the electrically weakable adhesive.

The active surfaces may be provided such that a projection of the first active surface on the surface of the first carrier layer essentially surrounds a projection of the second active surface on the surface of the first carrier layer.

The active surfaces may be provided such that a projection of the first active surface on the surface of the first carrier layer and a projection of the second active surface on the surface of the first carrier layer at least partly overlap each other,

wherein the method further comprising providing an insulating layer between the first and second active surfaces, at least at the overlap.

The first active surface may be provided such that it forms a closed loop with its projection on the surface of the first carrier layer surrounding the projection of the second active surface on the surface of the first carrier layer, wherein the second active surface may be provided with a connecting portion extending out of the closed loop of the first active surface, and wherein the electrically insulating layer may separate the connecting portion of the second active surface from the first active surface.

The method may further comprise providing a non electrically weakable adhesive as a layer between the electrically weakable adhesive and a second carrier layer.

The method may further comprise the step fo providing a second carrier layer adhered to the first carrier layer and the active surfaces by said electrically weakable adhesive or said non electrically weakable adhesive.

The method may further comprise the step of providing the first carrier layer as a part of a first portion of a package and providing the second carrier layer as a part of a second portion of a package, wherein the first and second portions of the package is adapted to be connected to each other and thereby keep the package closed.

The method may further comprise the step of providing the first carrier layer as a part of a first package member and providing the second carrier layer as a part of a second package member, wherein the first and second package members are adapted to co-operate with each other and thereby form a closed package.

The electrically weakable adhesive may form a sealing layer.

The method may further comprise providing the first carrier layer as a part of a connecting element adapted to temporarily holding together a plurality of articles, the connecting element comprising a base member provided with a first adhesion area adapted to hold a first secondary article to said base member and a second adhesion area adapted to hold a second secondary article to said base member, wherein the adhesion areas comprise an inventive laminate structure as disclosed in detail above.

### BRIEF DESCRIPTION OF THE DRAWINGS

The invention will by way of example be described in more detail with reference to the appended schematic drawings, which shows presently preferred embodiments of the invention.

FIG. 1 shows in an exploded view a first embodiment of a basic structure in accordance with the invention with the active surfaces arranged on the same side of the adhesive layer.

FIG. 2 shows in an exploded view a second embodiment of the basic structure of FIG. 1.

FIG. 3 shows a cross-section of the structure in FIG. 2.

FIG. 4 shows in an exploded view of a third embodiment of the basic structure of FIG. 1.

FIG. 5 shows an embodiment where twelve packages are being held together by two panels.

FIG. 6-8 indicate three different alternatives of how an electrical energy may be applied in order to weaken the adhesive.

FIG. 6 shows a first embodiment of a panel as shown in FIG. 5.

FIG. 7 shows a second embodiment of a panel as the one shown in FIG. 5.

FIG. 8 shows a third embodiment of a panel as the one shown in FIG. 5.

FIG. 9 shows three packages held together to form a distribution unit.

FIG. 10a shows two packages of the kind shown in FIG. 9 after they have been separated from each other.

FIG. 10b shows in enlargement a portion of the package of FIG. 10a.

FIG. 11a shows in cross-section a package.

FIG. 11b shows in cross-section the package of FIG. 11a when opened.

FIG. 12 shows a portion of a bottle neck provided with a screw cap.

### DETAILED DESCRIPTION OF PREFERRED EMBODIMENTS

The basic structure comprises a first carrier layer 1 and a second carrier layer 2. A first active layer 3 is laminated on the first carrier layer 1. A second active layer 4 is laminated on the second carrier layer 2. The active layers are bonded together by a bonding layer 5, which bonding layer comprises an electrically weakable adhesive.

The electrically weakable adhesive may bridge the complete distance between the active layers but may also be completed with additional layers of other materials capable of performing the necessary electrical and/or mechanical connection. Such materials may be conventional non electrically conductive adhesives, polymers, varnishes, or the like, or electrically conductive versions of respective material.

FIG. 1-4 show embodiments wherein the active surfaces are arranged on the same side on a first carrier layer. In FIGS. 1, 2 and 4, the different layers are for clarity reasons illustrated at a distance from each other. However, it is apparent that in practice the layers forms a laminated structure. From the description below it will follow in which cases the different disclosed layers need to be in direct contact with each other and when there may be one or more additional, non-disclosed layers between the disclosed layers. It may also be noted that in direct contact may dependent upon the situation mean in mechanical contact or in electrical contact.

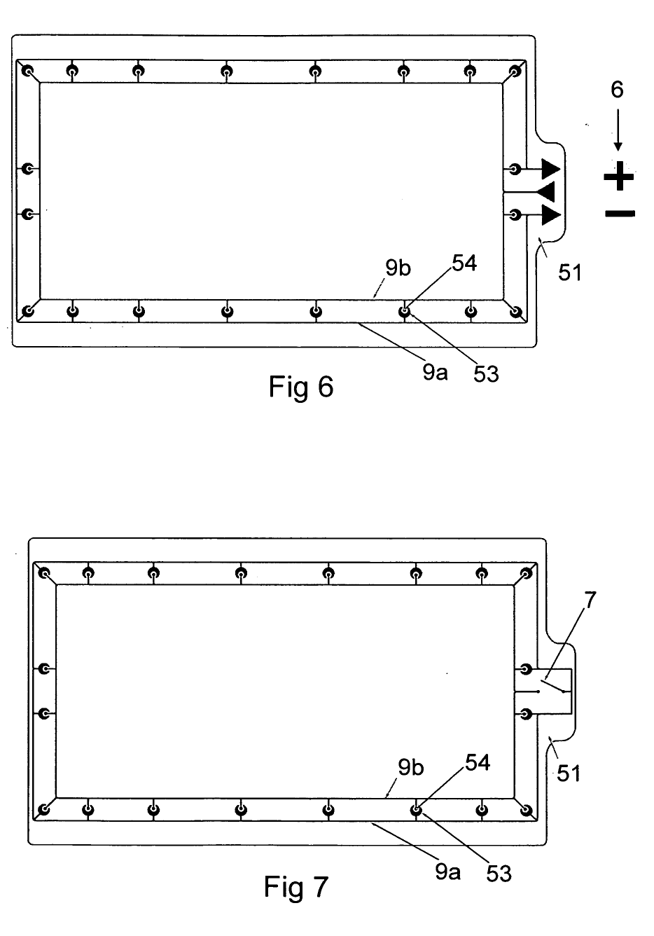

FIG. 6-8 shows a connecting element with three different alternatives of how to apply the electrical energy to break or weaken the bond of the bonding layer.

In FIG. 6 and in FIG. 1-4, the electrical potential difference between the active layers 3, 4 is adapted to be provided by an external source 6 of electrical energy (indicated by the + and − signs). This external source may e.g. be a battery provided in a handheld device, or a battery being attached to the package and connectable to the active layers 3, 4. One or several batteries can, e.g., be printed on one of the carrier layer and connected to the active surfaces. In this design the two active layers 3, 4 may, but need not, be formed of the same material. When a voltage is applied between the active surfaces 3, 4, current will flow between the active surfaces 3, 4 via the bonding layer 5. This will cause the bonds in the bonding layer 5 or between the bonding layer 5 and one or both of the active surfaces 3, 4 to break or to weaken. The current applied may be in the form of direct current or alternating current. A direct current is preferably used to weaken the bonds in the bonding layer 5 or between one of the active surfaces 3 or 4 and the bonding layer 5. An alternating current is preferably used to weaken the bonds in the bonding layer 5 or between both of the active layers 3, 4 and the bonding layer 5.

In FIG. 7, the electrical potential difference between the active layers 3, 4 is adapted to be provided by making the active layers 3, 4 of different materials with different electrode potentials. If the two active layers 3, 4 are connected, e.g. by moving a switch 7 to a position where it connects the two layers 3, 4, a closed circuit is formed and current will flow through the bonding layer 5, thereby causing the adhesive bond to break or weaken. For example, copper and graphite can be used as active layers 3, 4 with different potentials. This design will create a flow of direct current between the active layers 3, 4 via the bonding layer 5.

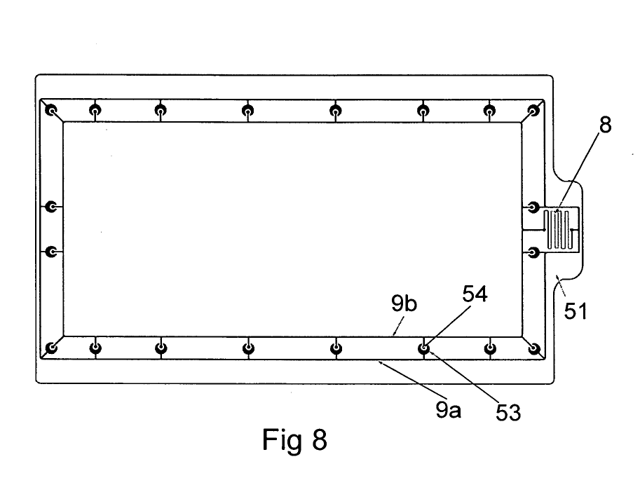

In FIG. 8, the electrical potential difference between the active layers 3, 4 is provided by supplying electro magnetic waves, e.g. radio waves, to the package. The active layers 3, 4 or a separate member 8 connected to the active layers 3, 4 may be adapted to be subjected to the electro magnetic waves and transform this wave to an electrical potential difference between the active layers 3, 4. The AC voltage generated by the electro magnetic waves can be can be used directly or transformed to DC voltage by a rectifier, e.g. a half-wave rectifier or a full-wave rectifier, connected to the active surfaces.

This member 8 may, e.g., be an antenna or a coil. In this design the two active layers 3, 4 may, but need not, be formed of the same material.

Although the discussion concerning the different manners of providing the electrical potential difference or voltage has referred to FIG. 6-8, the teachings may be used in respect of the different applications of the laminate structure as deemed suitable.

The use of controlled delaminating material in the collation of products in transit or handling and subsequent separation of the products, diminish the need for extra material and facilitate the distribution of products.

The connecting elements and packages described in the following make use of an electrically weakable adhesive material. The inventive connecting elements and packages are provided with two active surfaces, being electrically conducting and acting as electron and/or ion emitter and receiver, connected with a bonding layer formed by the electrically weakable adhesive material. The bonding layer possesses adhesive properties and conductive properties. When a voltage is applied between the active surfaces and current flows through the bonding layer, bonds formed in or between the bonding layer and at least one of the active surfaces are broken or weakened. Thus, the bonding layer forms an electrically weakable adhesive.

The electrically weakable material and different basic configurations of the active surfaces will initially be discussed in detail separately from the specific designs of the different uses. The different uses will thereafter be discussed in detail. In some cases the design of the package will be discussed in combination with a specific kind of basic configuration. It should however be noted that this is for exemplifying purposes and that the different basic configurations may be combined with the different designs of the packages.

According to one embodiment the bonding layer is composed of a composition possessing both matrix functionality and electrolyte functionality. The matrix and the electrolyte functionalities may be formed by a single phase or several separate phases.

The matrix functionality provides the adhesive properties necessary to bind surfaces to one another mechanically or chemically. The matrix functionality may be provided by polymers, polymer resins or fibers that possess adhesive properties.

The electrolyte functionality provides the ion conductivity necessary to support a faradic reaction, i.e. an electrochemical reaction in which a material is oxidized or reduced, or some other chemical/physical reaction. The materials are preferably chosen and designed such that the reaction occurs at the interface between one or both of the active surfaces and the bonding layer. Alternatively the bonding layer may be designed such that the reaction will occur within the bonding layer. This may, e.g., be accomplished by providing islands of a material with electrolyte functionality within the matrix material. The electrolyte functionality may be provided by adding a salt to the material or by modifying the polymer so that it includes ion-coordinating moieties.

The electrically weakable adhesive used in the inventive packages may be the electrochemically disbondable composition ElectRelease™ supplied by EIC laboratories and disclosed in more detail in U.S. Pat. No. 6,620,308.

FIG. 1 shows an embodiment wherein the active surfaces 3, 4 are arranged on the same side of the bonding layer, which bonding layer comprises an electrically weakable adhesive. The structure comprises two carrier layers 1, 2 that are to be delaminated. The carrier layers 1, 2 may, e.g., be made of paper, paper board or plastic, but other materials are contemplated. The active surfaces 3, 4 are arranged on one side of the bonding layer 5 and are separated from each other a distance d along the surface 5a of the carrier layer 1

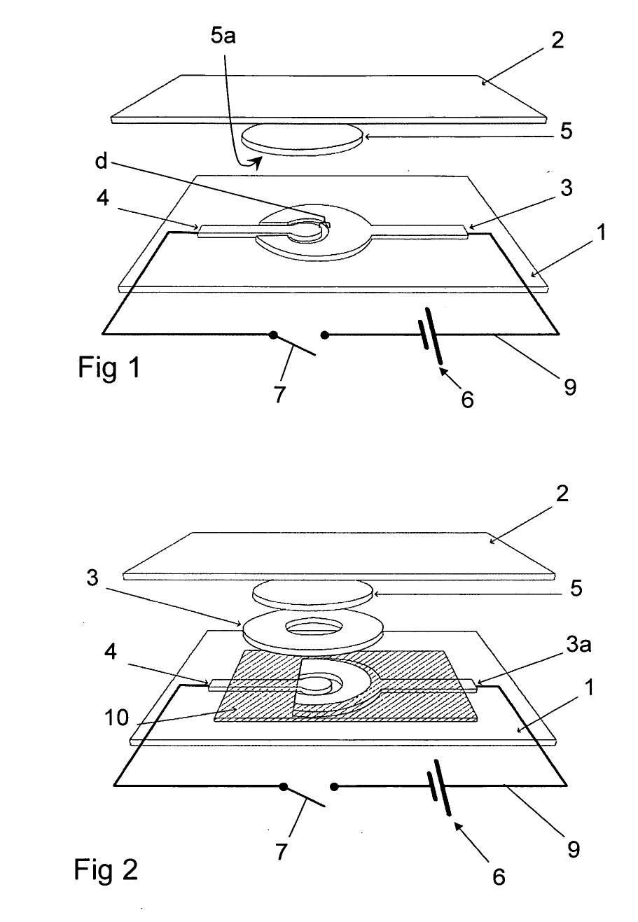

The active surfaces 3, 4 may be applied to the first carrier layer 1 using any conventional method, they may, e.g., be printed or laminated onto the carrier layer 1. The active surfaces 3, 4 may be made of any conductive material, e.g. metal ink or foil. The bonding layer 5 is provided between respective active surface 3, 4 and the second carrier layer 2, thereby bonding the active surfaces 3, 4 to the second carrier layer 2 and in turn thereby bonding the two carrier layers 1, 2 to each other. The bonding layer 5 typically reaches the first carrier layer 1 in the small accessible area formed by the gap or distance d between the active surfaces 3, 4. As shown in FIG. 2, one of the active surfaces 3 has an area of distribution formed as an open half-circle partially enclosing the other active surface 4. This other active surface 4 has an area of distribution formed as a circle. The two active surfaces 3, 4 form a gap formed as a part of a ring, in this case a part of a circular ring, having a width defined by the above mentioned distance d. Other shapes, such as squares are also contemplated.

The active surfaces 3, 4 are also connected or connectable to each other via a circuit 9 comprising an external power supply 6 and a switch 7.

When a voltage is applied between the active surfaces 3, 4, e.g. by the closure of the switch 7, current will flow between the active surfaces 3, 4 via the bonding layer 5. This will cause the bonds in the bonding layer 5 or between the bonding layer 5 and one or both of the active surfaces 3, 4 to break or to weaken. The accessible area of the first carrier layer 1 between the active surfaces 3, 4 may be made so small that even if the bonding layer 5 reaches the first carrier layer 1, the force needed to break the bond between this accessible area and the bonding layer 5 is negligible. The power supply 6 can, e.g., be at least one battery that is printed or laminated on the carrier layer 1 and connected to the active surfaces 3, 4. In this way, the battery 6 and the active surfaces 3, 4 can be printed or laminated on the carrier layer in the same process step. In order to increase the power supply, several batteries can be printed on the carrier layer 1 and connected to the active surfaces. This enables all batteries and the active surfaces to be printed on the carrier layer in the same process step, which facilities the manufacturing of the structure.

In an alternative embodiment to the one shown in FIG. 1, the active surfaces 3, 4 are formed of different materials with different potentials. In such an embodiment the external power supply 6 may be dispensed with. When the circuit 9 is closed by the switch 7, current will flow between the active surfaces 3, 4 via the bonding layer 5, which will cause the bonds in the bonding layer 5 or between the bonding layer 5 and one or both of the active surfaces 3, 4 to break or to weaken.

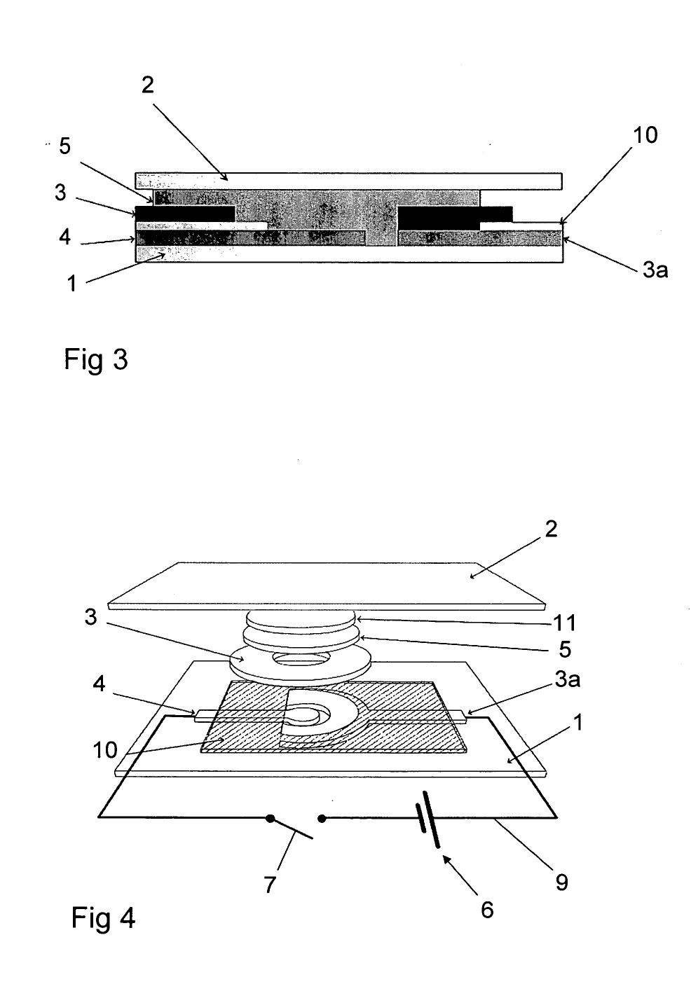

FIG. 2 and 3 shows yet another embodiment of a kind similar to the one shown in FIG. 2. In the embodiment of FIG. 3 and 3, the active surfaces 3, 4 are separated out of the plane by an insulating layer 10, but are still on the same side of the bonding layer 5 compared to the second carrier layer 2. The first active surface 3 is electrically connected to a connector 3a that formed part of the first active surface 3 in the embodiment of FIG. 2.

The insulating layer 10 separates the conducting elements and protects them from tear and wear. The connector 3a is in contact with the first active surface 3, but there is no direct connection between the connector 3a and the second active surface 4.

The second active surface 4 is provided on the carrier layer 1 as in the embodiment of FIG. 1. The insulating layer 10 is provided on this structure. Above the insulating layer 10 is the first active surface 3 arranged, and finally on top of this is the bonding layer 5 arranged. Since the first and second active surfaces 3, 4 are separated out of the plane, the first active surface 3 may be formed as a circular member completely surrounding the circular end portion of the second active surface 4. The active surfaces 3, 4 and the insulating layer 10 provides a gap between the active surfaces 3, 4 adapted to be bridged by the bonding layer 5. The bonding layer 5 may extend all the way from the second carrier layer 2 to the first carrier layer 1 and thereby provide a direct adhesion between the first and second carrier layer 1, 3.

The active surfaces 3, 4 are also connected or connectable to each other via a circuit 9 comprising an external power supply 6 and a switch 7.

When a voltage is applied between the active surfaces 3, 4, e.g. by the closure of the switch 7, current will flow between the active surfaces 3, 4 via the bonding layer 5. This will cause the bonds in the bonding layer 5 or between the bonding layer 5 and one or both of the active surfaces 3, 4 to break or to weaken. The accessible area of the first carrier layer 1 between the active surfaces 3, 4 may be made so small that even if the bonding layer 5 reaches the first carrier layer 1, the force needed to break the bond between this accessible area and the bonding layer 5 is negligible.

In an alternative embodiment to the one shown in FIGS. 2 and 3, the active surfaces 3, 4 are formed of different materials with different potentials. In such an embodiment the external power supply 6 may be dispensed with. When the circuit 9 is closed by the switch 7, current will flow between the active surfaces 3, 4 via the bonding layer 5, which will cause the bonds in the bonding layer 5 or between the bonding layer 5 and one or both of the active surfaces 3, 4 to break or to weaken.

FIG. 4 shows an alternative embodiment to the one shown in FIG. 2 and 3, wherein the bonding layer 5 is adapted to carry a second bonding layer 11. This second bonding layer 11 may be formed of an adhesive that do not have to be conductive or electrically weakable. By providing this second bonding layer it is possible to pre-manufacture the first carrier layer 1 with the active surfaces 3, 4 and the bonding layer 5, and then finally apply a second bonding layer 11 on the electrically weakable bonding layer 5 when the second carrier layer 2 is to be fastened to the first carrier layer 1. This additional bonding layer 11 may also be used in the design disclosed in FIG. 2.

An artisan will realize that there exists several alternatives to and combinations of the above disclosed embodiments. A brief discussion of some these alternatives follow hereinafter.

Respective active surface/layer may be arranged directly or indirectly via a laminating layer or the like on respective carrier layers. The active layer may in it self form both active surface and carrier layer.

As mentioned above the active surfaces may be separated in the plane and/or out of the plane. In order to separate the active surfaces out of the plane, an insulating layer, e.g. varnish, may be used. Insulating layers may also be used to separate conductive elements, such as active surfaces, from the carrier layer in cases when the carrier layer is conductive. Additional conductors may be arranged e.g. between the bonding layer and the second carrier layer in order to increase the conductivity in the plane of the structure.

The active surfaces are electrically conductive surfaces, conductors, and are preferably coated, printed or laminated on at least one carrier layer. However, if the carrier layers are electrically conductive, no extra active surfaces are needed. The active surfaces may be composed of any electrically conductive material, e.g. copper, aluminium or graphite. The active surfaces may for example be in the form of a metal ink.

The carrier layer represent surfaces that are to be delaminated by the electrical force and can be of any conductive or non-conductive material, e.g. paper, paper board, glass, metal, wood, moulded fibers or plastic. Two opposite sides of an opening of a package may for example represent a first and a second carrier layer. This will discussed in more detail below.

In accordance with one embodiment-the carrier layers are formed of carton boards and the active layers are formed of an aluminium foil with oxide. The active surfaces are moisturized with a salt solution and bonded together using a composition comprising polyurethane. When an electrical potential difference is applied over the laminate structure, the aluminium oxide on the positively charged foil dissolves whereby the laminate is broken.

The delaminating material structure described above may be used whenever the strength of a seal needs to be released, for example in the construction of packages. By providing the material structure as described above the packages may be opened by the application of a voltage. It can be used in all kinds of packages, such as cans, jars, bottles, cartons and blister packages. It may also be used together with all kinds of materials, such as paper, paper board, glass, metal, wood, moulded fibers or plastic. Two opposite sides of an opening of a package may represent a first and second carrier layer and the delaminating material described above may be arranged between the carrier layers.

Furthermore, the controlled delaminating material may be used for collation of products in transit or handling and subsequent separation of the products, for separating packages bonded together and for tamper-proofing goods. It may also be used to limit or change the properties of a product before it is purchased in order to prevent theft. Collation of products, tamper-proofing a product or preventing theft of a product may be done by binding existing parts or elements of the product or products together or by binding additional elements to the product or products, using the controlled delaminating material.

In one embodiment for holding packages together, a connecting element is adapted to temporarily hold together a plurality of packages, which connecting element has a first adhesion area adapted to hold a first package to the body and a second adhesion area adapted to hold a second package to the body. The adhesion areas further comprise an electrically weakable adhesive, i.e. a bonding layer. The connecting element is provided with a set of active layers adapted to conduct an electric current through the bonding layer.

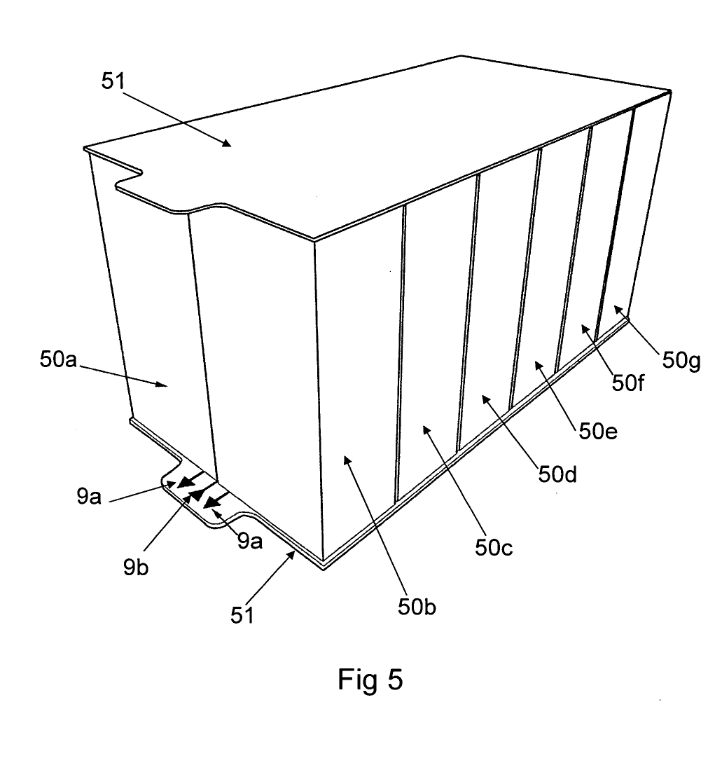

FIG. 5 shows an application wherein a full pallet of packages 50a-g are interlocked using a connecting element 51 which make use of a controlled delaminating material. Interlocking a full pallet saves packages from damage or from distorting during distribution. Individual packages 50a-g are collated by the attachment of a connecting element 51, for example a carton board sheet 51. The surface, or parts of the surface, of the board sheet 51 facing the packages is printed with active layers 53, 54 and a bonding layer possessing adhesive as well as conductive properties is applied between the active layers 53, 54 and the packages 50 to be interlocked. In store, the packages 50 may be released and displayed on the pallet by the application of a voltage across the active layers 53, 54 whereby current will flow through the bonding layer causing a disbanding reaction to occur in the bonding layer or at the interface between the bonding layer and one or both of the active layers 53, 54.

FIG. 6-8 show examples of how the active layers 53, 54 may be arranged at the carton board sheet 51.

FIG. 6 shows an example wherein a first circuit 9a is printed at a carton board sheet 51. A second circuit 9b is printed on the board sheet at a distance from the first circuit 9a. In connection with said first circuit 9a, a first set of active surfaces 53 are arranged at short intervals on said board sheet. A second set of active surfaces 54 are arranged in connection with said second circuit 9b. Respective second active surface 54 is arranged at a small distance from respective first active surfaces 53. This has been disclosed in more detail with reference to FIG. 1-4.

Respective active surfaces 53, 54, arranged at a small distance from each other, form a pair of active surfaces 53, 54. A bonding layer is applied between the active surfaces 53, 54 and the packages 50a-g. The bonding layer is applied in spots such that each spot covers each pair of active surfaces 53, 54. The set of active surfaces 53, 54 and electrically weakable adhesive forms an electrically weakable adhesion area. As shown in FIG. 6-9 a plurality of such pairs of active surfaces 53, 54 and the accompanying electrically weakable adhesive is arranged along the circumference of the connecting element 51. The connecting element 51 of FIG. 6 is adapted to be connected to an external source 6 of electrical energy (indicated by the + and − signs). When the connecting element 51 is connected to the external source 6 current will flow in the first and second circuits 9a, 9b via each pair of active surfaces 53, 54 and conducting, electrically weakable adhesive.

In the embodiment shown in FIG. 7, the active surfaces 53, 54 are of different materials with different potentials. Preferably, also the circuits 9a, 9b are of respective materials of different potentials. The circuits 9a, 9b may be connected by a switch 7. When the switch is open, no current flows through the bonding layer 55. When the switch is closed, current will flow through the bonding layer between the active surfaces 53, 53 thereby causing bonds in the bonding layer or between the bonding layer and one or both of the active surfaces 53, 54 to break or to weaken.

In yet another alternative embodiment, the electrical energy may be generated by the application of electromagnetic waves. FIG. 8 shows an example of an embodiment wherein electromagnetic waves, such as radio frequencies, generates current in an antenna 8 arranged between said circuits 9a, 9b.

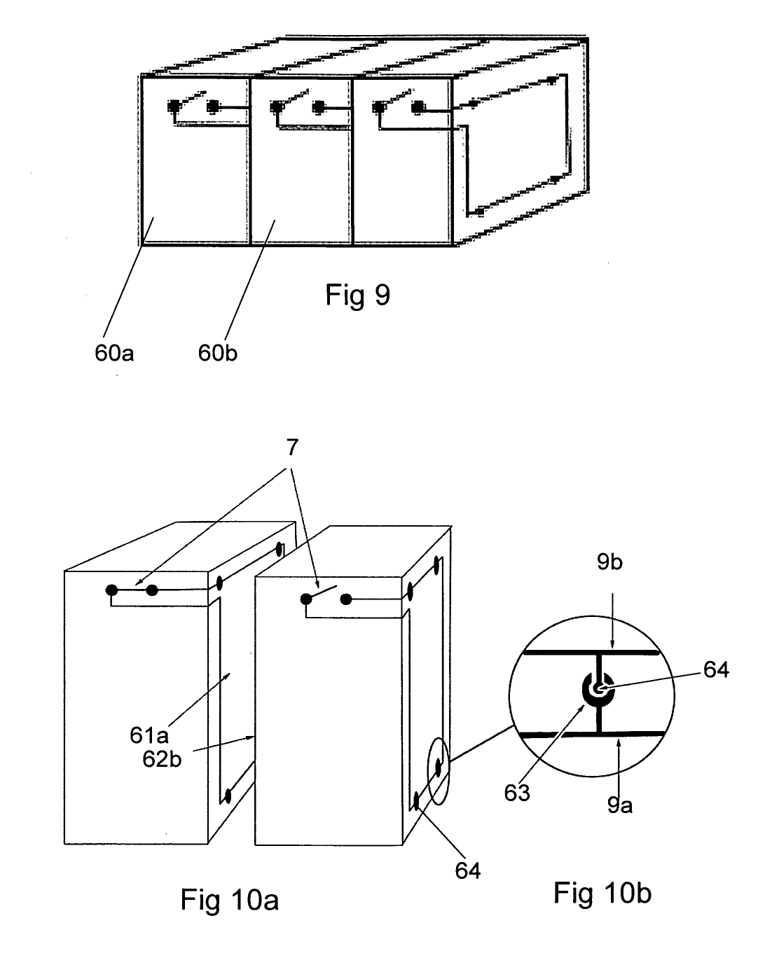

In an alternative embodiment for holding packages together, the packages may be held together directly using controlled delaminating materials. In one example of this embodiment, multi packs are held together and released after purchase. Such a design is shown in FIG. 9 and FIG. 10a-b.

FIG. 9 is a schematic drawing, which shows an example wherein three packages are held together using controlled delaminating materials.

The principle will be discussed in more detail with reference to FIG. 10a-b, wherein two packages has been separated slightly in order to make all components visible.

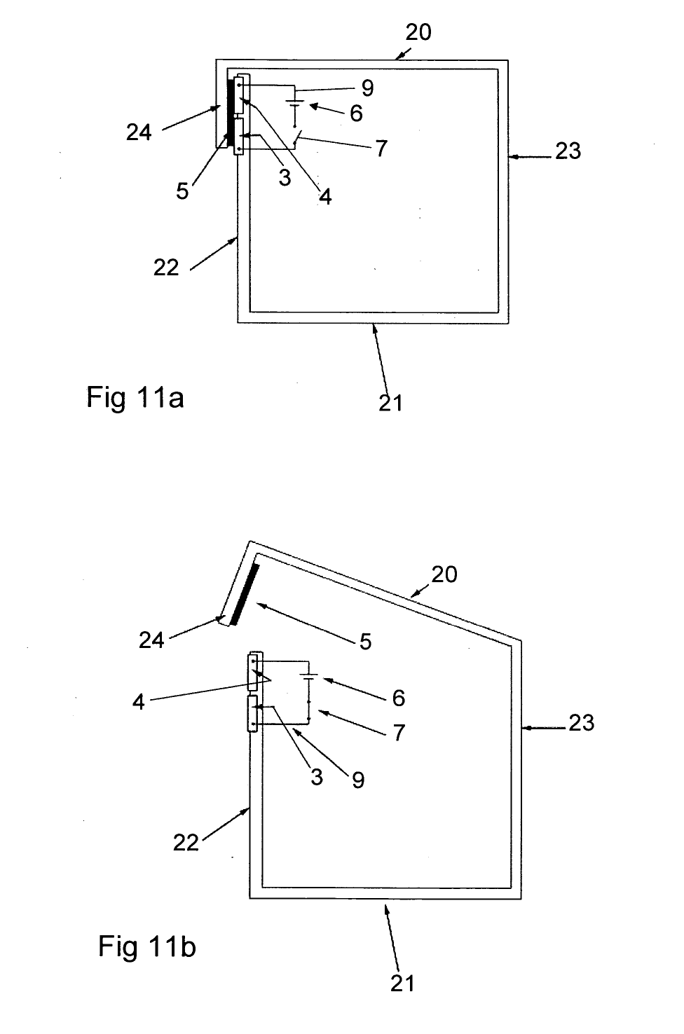

In FIG. 9 and FIG. 10a-b the left package 60a is provided with a double connector circuit 9a, 9b (as shown in detail in FIG. 7-9 and a switch 7 located on an accessible side 60a′ of the package 60a. The circuits 9a, 9b extends to a surface 61a facing a neighboring package 60b. The circuits 9a, 9b extend essentially along the perimeters of the surface 61a facing the neighboring package 60b and are as shown in detail in FIG. 11b provided with active surfaces 63, 64 and an electrically weakable adhesive layer 65.

Thus, in this example, the side 61a of the package 60a forms the first carrier layer. The active surfaces 63, 64 and the circuits 9a, 9b may be arranged on the said surface 61a of the package 60a in a pattern similarly to the one described above with reference to FIG. 1-4. Spots of bonding layers may be applied between each pair of active surfaces and the side 62b of the other package 60b facing the first package 60a, whereby the packages are glued together. When the circuit 9a, 9b is open no current flows through the bonding layer 65, and the packages 60a, 60b remains glued together. When the circuit 9a, 9b current will flow through the bonding layer 65 causing bonds therein or between the bonding layer 65 and one or both of the carrier layers 61a, 62b to break or to weaken, and the packages may easily be separated. As an example, the circuit 9a, 9b may be closed by the user pressing a button arranged on the outside on the package, which causes a switch 7 to close. The current needed to break or weaken the bonds may be applied by any of the methods described above. Thus, the active surfaces 63, 64 may be of different materials with different potentials. Alternatively, the electrical energy may be applied by an external electrical source or it can be generated by electromagnetic waves. Further layers may be applied between the two connected surfaces of the packages; such layers may be insulating layers, further conducting layers or layers of conventional adhesives as described above.

The packages described in the following make use of an electrically weakable adhesive material. FIG. 11-15 disclose examples of uses and applications in different kind of packages.

FIG. 11a-b discloses in cross-section a package provided with a closure adapted to be opened using the electrically weakable laminated structure described above.

The package comprises a top panel 20, a bottom panel 21, a front panel 22, a back panel 23 and two side panels (in front of and behind the cross-section of FIG. 6a-b). A closure flap 24 is connected to or integrally formed with the top panel 20. The closure flap 24 is folded relative to the top panel 20, extends along a portion of the front panel 22 and is fastened to the front panel 22 using the electrically weakable laminated structure described above.

Two active surfaces 3, 4 are arranged side by side, but not in direct contact, on one side of the opening closed by the top panel 20. The active surfaces 3, 4 are arranged on the outside of the front panel 22 facing the closure flap 24. A bonding layer 5 is applied between the active surfaces 3, 4 and the closure flap 24, thereby bonding the active surfaces 3, 4 to the closure flap 24. An electrical circuit 9 is provided to electrically connect the active surfaces 3, 4. The circuit is schematically drawn to include a switch 7 and a voltage supply 6. This has been discussed in more detail with reference to basic laminate structure of FIG. 1-4 and the connecting element of FIG. 6-9.

In FIG. 11a, the switch 7 is open, no current flows through the bonding layer 5 and the closure flap 24 remains bonded to the active surfaces 3, 4 and, consequently, to the front panel 22. In FIG. 6b, the switch 7 is closed, a closed circuit is formed, current flows through the bonding layer 5, thereby causing bonds in the bonding layer 5 or between the bonding layer 5 and one or both of the active surfaces 3, 4 to break or to weaken, whereby the package may easily be opened.

FIG. 11 is a schematic picture showing the principle. Although not shown in FIG. 11, the circuit 9 and the switch 7 may be arranged such that the user that wants to open the package presses a button arranged on the outside of the package, which causes the switch to close and the bonds in the bonding layer to break or to weaken. Furthermore, insulating layers may be arranged in order to separate the active surfaces 3, 4 out of the plane as described above with reference to FIG. 1-4 and a conventional non-conducting adhesive may be arranged between the bonding layer 5 and the closure flap 24. It may also be noted that, in contrast to FIG. 6 where the front panel 22 constitutes the first carrier layer 1 and the closure flap 24 constitutes the second carrier layer 2, the closure flap 24 may constitute the first carrier layer 1 and the front panel 22 of the package may constitute the second carrier layer 2.

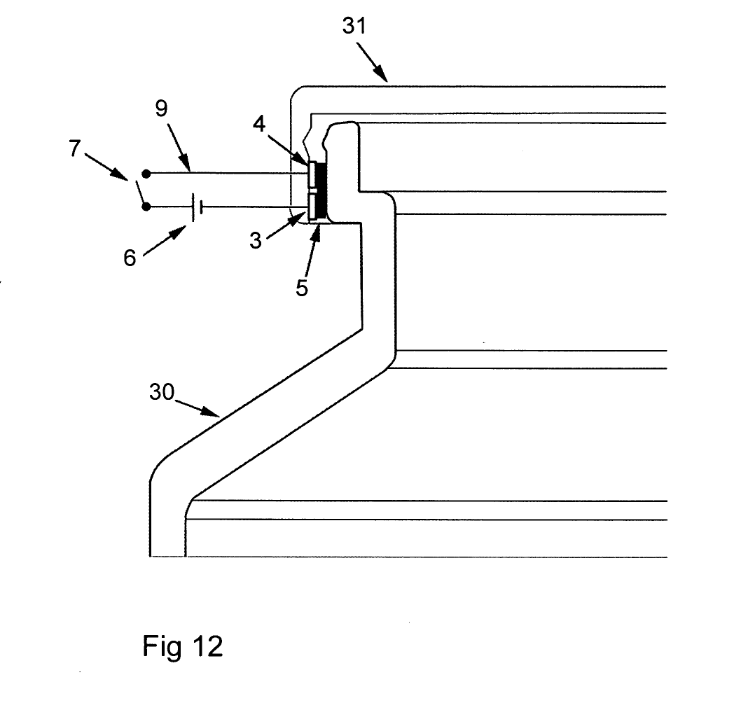

FIG. 12 shows another embodiment of a package adapted to be opened by the application of an electrical force, which package comprises two parts, a container 30, which is adapted to receive a product, and a cap 31. The package may for example be a bottle, but any kind of package is possible. The active surfaces 3, 4 are arranged at a distance from each other on the surface of the cap 31 facing the container 30. A bonding layer 5 is applied between the active surfaces 3, 4 and the surface of the container 30 facing the cap 31. The bonding layer 5 glues the cap 31 to the container 30. The active layers 3, 4 are connected by a circuit 9 comprising a switch 7 and a voltage supply 6. When the switch 7 is open, no current flows between the active surfaces 3, 4 or through the bonding layer 5 and the cap remains glued to the container 30. When the switch 7 is closed and current flows through the bonding layer 5, the bonds in the bonding layer 5 or between the bonding layer 5 and one or both of the active surfaces 3, 4 are broken or weakened, whereby the container 30 may easily be opened.

Furthermore, insulating layers may be arranged in order to separate the active surfaces 3, 4 out of the plane as described above with reference to FIG. 2-5 and a conventional non-conducting adhesive may be arranged between the bonding layer 5 and the container 30 or the cap 31. It may also be noted that, in contrast to FIG. 7 where the cap 31 constitutes the first carrier layer 1 and the container 30 constitutes the second carrier layer 2, the container 30 may constitute the first carrier layer 1 and the cap 31 may constitute the second carrier layer 2.

The inner envelope surface of the cap 31 and the outer envelope surface of the neck of the container 30 may be threaded, whereby the cap is screwed on the container. The threads may extend about the complete circumference of the neck or only partly as in a bayonet connection often used in glass jars and metal lids. In such an embodiment the controlled delaminating material may serve as a tamper proof or as an easily breakable sealing layer.

1. Laminate structure comprising a first carrier layer with a surface, a first active surface being electrically conducting and being supported by the first carrier layer, a second active surface being electrically conducting and being supported by the first carrier layer, wherein the first active surface is separated from the second active surface a first distance along the surface of the first carrier layer, wherein the laminate structure is adapted to receive an electrically weakable adhesive bridging said distance between the active surfaces.

2. Laminate structure according to claim 1, wherein the first carrier layer is formed of a non-conductive material.

3. Laminate structure according to claim 1, comprising an internal source of electrical power adapted to be activated or connected to the active surfaces to in a closed electrical circuit apply a voltage the electrically weakable adhesive.

4. Laminate structure according to claim 3, wherein the first active surface is of a first material with a first electrode potential, and the second active surface is of a second material with a second electrode potential, and wherein the first electrode potential differs from the second electrode potential.

5. Laminate structure according to claim 3, further comprising at least one printed and/or laminated battery.

6. Laminate structure according to claim 1, wherein a portion of at least one of said active surfaces is exposed and adapted to be covered by said adhesive.

7. Laminate structure according to claim 1, wherein at least a portion of the first active surface and at least a portion of the second active surface are exposed and adapted to be covered by said adhesive.

8. Laminate structure according to claim 1, wherein the active surfaces are connectable to each other via an electrical circuit comprising a switch member by which the circuit may be closed or opened.

9. Laminate structure according to claim 1, wherein the active surfaces are shaped such that a projection of the first active surface on the surface of the first carrier layer essentially surrounds a projection of the second active surface on the surface of the first carrier layer.

10. Laminate structure according to claim 1, wherein a projection of the first active surface on the surface of the first carrier layer and a projection of the second active surface on the surface of the first carrier layer at least partly overlap each other, wherein the laminate structure further comprises an insulating layer provided between the first and second active surfaces, at least at the overlap.

11. Laminate structure according to claim 10, wherein the first active surface is formed as a closed loop with its projection on the surface of the first carrier layer surrounding the projection of the second active surface on the surface of the first carrier layer, wherein the second active surface has a connecting portion extending out of the closed loop of the first active surface, and wherein the electrically insulating layer separates the connecting portion of the second active surface from the first active surface.

12. Laminate structure according to claim 1, further comprising an electrically weakable adhesive bridging said distance between the first and second active surfaces, and being adapted to be located between the active surfaces and a second carrier layer.

13. Laminate structure according to claim 12, further comprising a non electrically weakable adhesive arranged as a layer adapted to be located between the electrically weakable adhesive and a second carrier layer.

14. Laminate structure according to claim 12, further comprising a second carrier layer adhered to the first carrier layer and the active surfaces by said electrically weakable adhesive or said non electrically weakable adhesive.

15. Laminate structure according to claim 14, wherein the first carrier layer forms part of a first portion of a package and the second carrier layer forms part of a second portion of a package, wherein the first and second portions of the package is adapted to be connected to each other and thereby keep the package closed.

16. Laminate structure according to claim 14, wherein the first carrier layer forms part of a first package member and the second carrier layer forms part of a second package member, wherein the first and second package members are adapted to co-operate with each other and thereby form a closed package.

17. Laminate structure according to claim 15, wherein the electrically weakable adhesive forms a sealing layer.

18. Laminate structure according to claim 1, wherein the first carrier layer forms part of a connecting element adapted to temporarily holding together a plurality of articles, the connecting element comprising a base member provided with a first adhesion area adapted to hold a first secondary article to said base member and a second adhesion area adapted to hold a second secondary article to said base member, wherein the adhesion areas comprise a laminate structure according to claim 1.

19. Method of producing a laminate structure, the method comprising:
providing a first carrier layer,
providing a first active surface being electrically conducting and being supported by the first carrier layer,
providing a second active surface being electrically conducting and being supported by the first carrier layer and separated from the first active surface a first distance along the surface of the first carrier layer, and
providing a layer of an electrically weakable adhesive at least partly bridging said distance between the first and second active surfaces.
